(19) United States
(12) Patent Application Publication
(10) Pub. No.: US 2016/0233595 A1
(43) Pub. Date: Aug. 11, 2016

(54) APPARATUS AND METHOD FOR CONNECTING A CABLE TO A HIGH TEMPERATURE CIRCUIT

(71) Applicant: ADVANTEC SENSING AS, Stord (NO)

(72) Inventor: Tore Gundersen, Rykkinn (NO)

(21) Appl. No.: 15/022,544

(22) PCT Filed: Jun. 2, 2014
(86) PCT No.: PCT/NO2014/050089

§ 371 Date: Mar. 16, 2016

(30) Foreign Application Priority Data
Sep. 16, 2013 (NO) 20131252

(51) Int. Cl. H01R 12/58; H01R 43/02; G01D 5/24; H05K 1/14

(52) U.S. Cl. CPC H01R 12/58; H05K 1/144; H01R 43/0256; G01D 5/24; H05K 2201/10151; H05K 2201/10257; H05K 2201/10303; H05K 2201/10356; H05K 2201/2036

(57) ABSTRACT

Connecting a capacitive measuring probe at elevated temperatures is achieved by direct attachment of metallic connecting components on a temperature substrate. A method and apparatus for a high temperature cable to circuit board connection involves a set or plurality of connecting elements that are soldered directly on the circuit board and a set or plurality of mating connecting elements that are soldered to a secondary circuit board having soldering pads for a cable.

### TECHNICAL FIELD OF THE INVENTION

The invention relates to a device for connecting a cable to a circuit board at temperatures where conventional connection components based on polymers melt or soften to a degree that causes a malfunction.

### BACKGROUND

In general applies that it is beneficial for detecting instrumentation that all or part of the instrument is close to the phenomenon or medium where physical values are to be detected or measured. Common physical values or parameters are pressure, temperature, and dielectric constant. Deriving the medium which is present can in many important situations made from the dielectric constant. In a majority of processing industries, among these the petroleum industry, it is beneficial to be able to determine the relationship between water, oil and gas in a pipe or a pressurized chamber. This can be done by known techniques with a probe in the pipe wall or the chamber, as disclosed in U.S. Pat. No. 6,420,882B.

If the medium in the pipe, chamber or tank is at high temperature, it will be beneficial that the probe is able to tolerate temperatures. In the prior art, electrical circuits are connected to cables to carry the measurement signals to a reading device at a certain distance from the measurement point. Advantageously parts of the electronics can be placed near the medium. This can be accomplished in that a separate circuit board, often of small dimensions, is placed in the measuring probe. Such a probe or sampling probe may for instance have the shape of a cylinder with a height and diameter of a few centimeters. This means that the circuit board is exposed to near the same temperature as the actual process temperature. Conventional electronic circuit boards typically do not withstand more than about 100° C. Ordinary connections and contacts of industry quality are equally not suitable for temperatures especially over 80°C. Recently, there occurred an enhanced need for circuits that may withstand temperatures as high as about 250°C. Using special components and heavy duty reinforced board substrate, electronic components and printed circuits can be made to operate at these temperatures. Sockets and connectors on the other hand are conventionally made of thermoplastic materials that melt or soften to become unusable at these high temperatures. The connection elements in connectors and couplers are typically made from metallic materials, and therefore exhibit beneficial resilience in the relevant temperature range.

### SUMMARY OF THE INVENTION

The invention provides a system and method for providing a cable to a primary high temperature circuit board connection, comprising provision of a high temperature circuit board carrying electronic components, together forming a high temperature electronic circuit, and a set or plurality of connecting elements of a first gender that are soldered directly on the a primary high temperature circuit board with a high temperature solder, and provision of secondary circuit board with a set or plurality of connecting elements of a second gender for mating with the connecting elements of the first gender to a secondary circuit board having soldering pads for a cable, wherein the connecting elements of the second gender are soldered directly on the secondary circuit board with a medium temperature solder.

According to the invention, the beneficial resilience in the relevant temperature range exhibited by the connection elements in connectors and couplers that are made from metallic materials, is exploited by combining the metallic connecting parts with a circuit board that can withstand high temperatures. In embodiments of the present invention, connecting parts of metal of a first gender, which could be connecting parts that are commercially available, are soldered into a primary high temperature electronic circuit board having thereon conducting paths and soldering pads or other suitable features for conductive connection and attachment of electronic components. The mating set of connecting parts can be soldered to a less temperature tolerant second board. Cables can then conveniently be soldered to this board.

### BRIEF DESCRIPTION OF THE DRAWINGS

FIG. 1 is a perspective view drawing of an example of a high temperature capacitive sensor electrical connection arrangement according to the invention, with the high and low temperature connection subassemblies separated from each other;

FIG. 2 is a perspective view drawing of the low temperature connection subassembly of an example of the connection arrangement illustrated in FIG. 1,

FIG. 3 is a perspective view drawing of a sensor housing adapted for forming a high temperature capacitive sensor in combination with the electrical connection arrangement of the invention;

FIG. 4 is a perspective view drawing of an novel high temperature capacitive sensor unit comprising the electrical connection arrangement of the invention;

FIG. 5 is a perspective view drawing of the novel high temperature capacitive sensor unit illustrated in FIG. 4;

FIG. 6 is a perspective view drawing of the novel high temperature capacitive sensor unit illustrated in FIGS. 4 and 5;

FIG. 7 is a side view drawing of the sensor housing illustrated in FIG. 4 together with parts of its mounting system comprising a threaded retainer ring and a plurality of solid spheres, shown separated from the housing,

FIG. 8A is a side view cross section drawing of the sensor housing and mounting system illustrated in FIG. 7;

FIG. 8B is an enlarged part of a right hand part of the side view cross section drawing of the sensor housing and mounting system illustrated in FIG. 8A;

FIG. 8C is an enlarged part of a right hand part of the side view cross section drawing of a further embodiment of the sensor installed in a wall of a hull or container, and comprising housing and mounting system with similarity to the embodiment illustrated in FIG. 8A rotated 180 degrees, and

FIG. 9 is a perspective view drawing of a temperature fluid level probe accommodating in a tubular probe housing two rows of a plurality of high temperature electronic capacitive sensors comprising the connection arrangement of the invention.

### DETAILED DESCRIPTION OF THE INVENTION

In the following, the invention will be explained by way of example, and with reference to the accompanying drawings of exemplary embodiments illustrating the novel and inventive aspects and features of the invention.

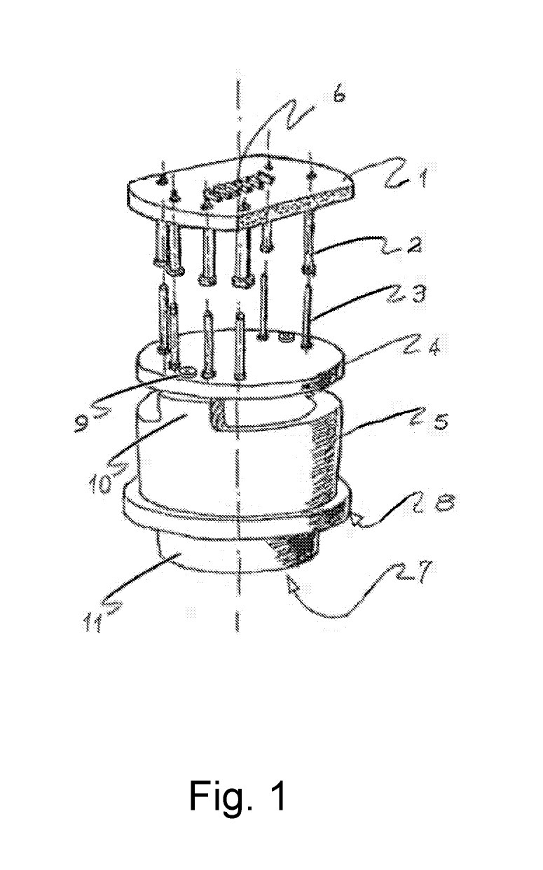

Reference is first made to FIG. 1, which shows elements of an embodiment of the invention being partially separated from each other, like in a “partially exploded view” drawing. A primary electronics board, which comprises a primary printed circuit board 4, PCB 4, fastened to a sensor housing 5. The PCB 4 is populated with various high temperature electronic components and integrated circuits, and is for connectivity provided with a plurality of first connecting members 3, which are metal connecting members of a first gender that are connected and attached by high temperature solder to conducting paths or pads on the PCB 4. The first gender is preferably the male gender, meaning in respect of the present invention, that the first connecting elements 3 are advantageously elongated connector pins of relatively small diameter, hence small cross section, adapted to be received in hollow first connecting member of a second gender in order to create a complete electrical connection arrangement according to the present invention. Accordingly, in respect of the present invention, the first gender is the male gender. Consequently, the second gender is the female gender. For the high temperature electronic capacitive sensor to function properly and to deliver predictable, stable and reproducible measurements, the PCB 4 is fastened by first fasteners 9 to raised portions 10 of one end of the housing 5, so as to be located as close as possible to the dielectric window 7 and the associated measuring capacitor plate electrode carried by the window, thereby minimizing thermal contact between the housing and the PCB 4, while obtaining stable electrical conditions within the sensor assembly and keeping a centrally located wire that connects the plate electrode to the electronics carried by PCB 4 as short and stable as possible. A connector board, hereinafter referred to as the secondary printed circuit board 1, PCB 1, is provided with a plurality of second connecting members 2, which are metal connecting members of the second gender, meaning in respect of the present invention a female, hollow connector, such as e.g. a socket or sleeve, adapted to receive the male, pin shaped first connecting member of the first gender, in order to create a complete electrical connection arrangement according to the present invention. In the arrangement of the invention, the second connecting members 2 are elongated metal connecting members having an outer diameter, hence cross section, that is substantially larger than an outer diameter, hence cross section, of the first connecting members 3. The PCB 1 has conventional conductive paths adapted to connect the second connecting members 2 with conducting pads 6 to which conductors of a cable (not shown) are soldered. By the connection arrangement provided by the present invention, heat transferred from the sensor housing 5 to the conductive pads 6, via the high temperature PCB 4, the first male connecting members 3, the second female connecting members 2 and the PCB 1, is considerably reduced, and conductors of a cable (not shown) are soldered to pads 6 by low temperature solder. By low temperature solder is meant solder used in commercial grade electronic equipment for operation in temperatures up to about 130° C. In the example illustrated in FIG. 1, six pads 6 have been shown.

Embodiments of the invention could rely on connecting elements that are well known to a person skilled in the art, and may favorably be with a cylindrical geometry in a male-female arrangement. In FIG. 1 is further shown that the circuit board 4 may typically be attached to a metallic sensor housing 5, and the housing 5 having a collar with a beveled sealing surface 8, so that the sensor can sealingly mounted to a hole in a wall of a sensor hull or sensor container with a correspondingly beveled contact sealing surface, so that the dielectric window 7 having an electrode on its surface may contact the medium in a tank or a pipe in which the sensor has been installed, while the electronics, the connecting arrangement and cables attached thereto are kept isolated from the surrounding medium which is to be measured or characterized by measurements of the electric capacitance of the medium.

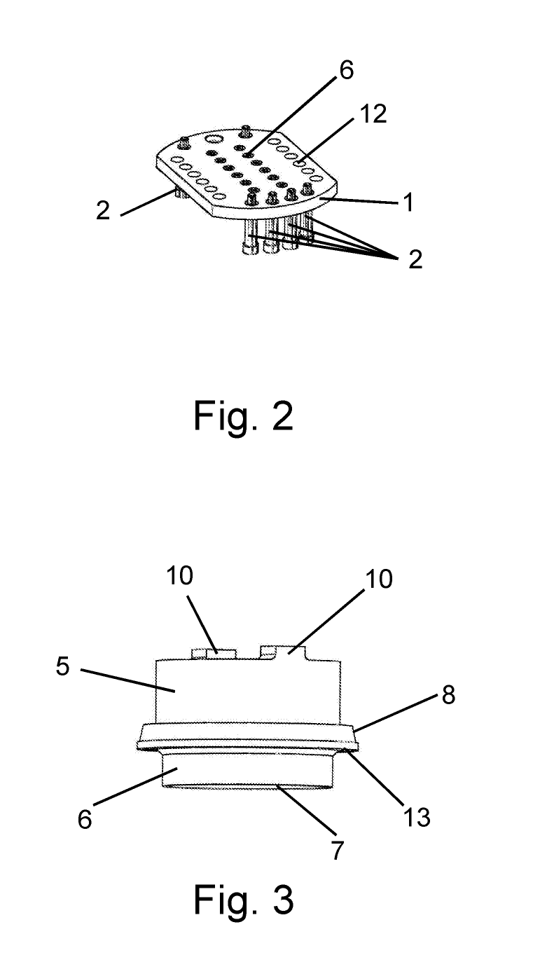

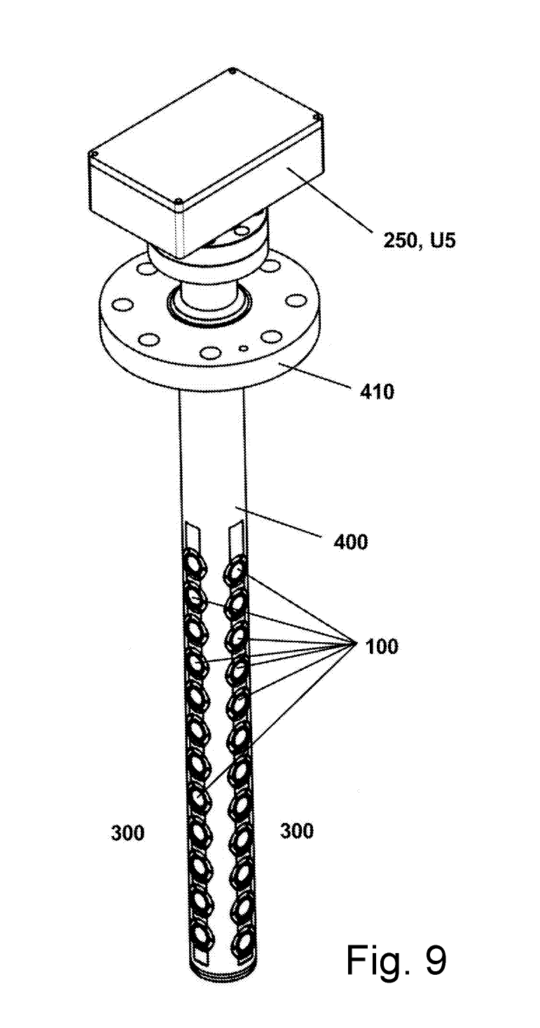

FIG. 2 shows an embodiment of the PCB 1 subassembly part of a connection arrangement according to the invention in a further perspective view illustration, having a total of six pairs of conductive pads for insoldering cable and six corresponding pairs of holes for guiding cable and providing strain relief. Each two pads 6 in a pair of pads are typically connected directly with each other, allowing for a power and signal bus of up to six conductors to be run through the PCB 1 of one sensor unit and onto the PCB 1 of a next, adjacently located sensor unit. Thereby, a high temperature probe comprising one or more rows of adjacently located high temperature sensor units can be built with a “daisy chain” like electrical interconnecting arrangement, such as e.g. the exemplary probe assembly illustrated in FIG. 9, which accommodates two rows of sensor units labeled 100 in a narrow, tubular probe housing labeled 400 having a probe sealing flange 410 and an “external” electronics housing 250 for accommodating therein further electronic circuitry and electric power supply U5, wherein each of the two rows includes twelve high temperature electronic capacitive sensor units with the connecting arrangement of the invention.

FIG. 3 illustrates further details of the sensor housing 5, in particular the raised portions 10 of the sensor housing for fastening the PCB 4 thereto, the cylindrical sensor housing “front” portion 11 to the inside of which the window is sealingly brazed, the surrounding collar portion of the housing having the beveled surface 8 to provide high pressure and high temperature proof sealing of the space at the “front” of the sensor with dielectric window from the space at the “back” of the sensor with plate electrode, electronics, connection arrangement and cables, and a race portion of the collar located inside of the beveled surface 6 and having a curved cross section for receiving a plurality of spheres that for part of a means for fastening the sensor housing to a circular opening in a wall of a hull or container in which the high temperature electronic capacitive sensor is to be mounted for making measurements of an electric capacitance of a medium that is to be measured or characterized.

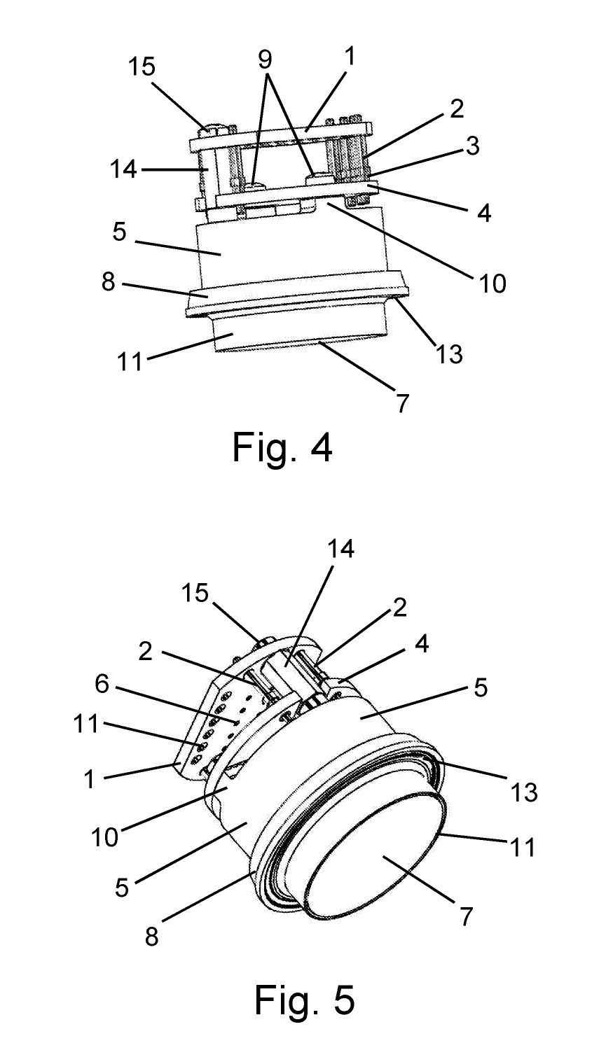

Referring now to FIG. 4, further details of the sensor incorporating the connection arrangement according to the invention is shown, including the fasteners 9 employed for attaching the PCB4 to the raised portions 10 of the sensor housing 5a standoff member 14 for positioning the PCB 1 correctly with respect to the PCB 4 so as to keep the connecting members 2 and 3 properly aligned and in correct engagement with each other for establishing electrical connections and for establishing a controlled thermal coupling, and fastener 15 adapted for engagement with standoff member 14 for keeping PCB 1 properly positioned and fixated with respect to the PCB 4 and the sensor housing 5. In this FIG. 4 is also indicated the location of the race 13 which forms a circular path around the collar, and is adapted to receive a plurality of spheres for applying an evenly distributed force on the collar and on the sealing surface 8 of the sensor housing.

Referring now to FIG. 5, the high temperature electronic capacitive sensor unit comprising the connecting arrangement of the invention is shown in a further perspective view, showing more of the race 13 encircling the main body of the sensor housing 5.

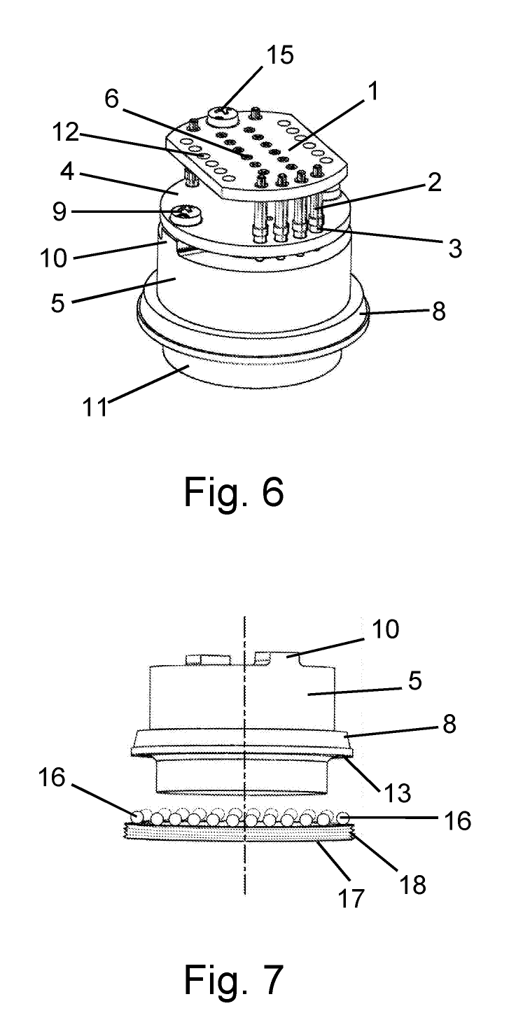

Referring now to FIG. 6, the high temperature electronic capacitive sensor unit comprising the connecting arrangement of the invention is shown in a further perspective view, showing more of the positions of the PCB1 and the PCB 4 relative to each other and to the sensor housing 5 and the dielectric window 7, for providing stable, well shielded and controlled electrical conditions for the capacitive measurements involving the electrode on the window 7 and the electronics of the PCB 4, while providing connectivity via soldering pads 6 to which a bus cable is soldered and low thermal coupling between the sensor housing 5 and the connections made on PCB 1.

Referring now to FIG. 7, more details of the arrangement for fastening the high temperature electronic capacitive sensor unit to a wall of a hull, container or probe housing is shown, including a threaded retainer ring 17 having threads on a circumference that are adapted for engagement with corresponding threads provided on an inner surface of a hole in the wall that is to receive and accommodate the high temperature electronic capacitive sensor unit sealingly attached to the hull, container or probe housing. In this FIG. 7, the PCB 1, the PCB 4 and fastener and standoff members are not shown. the retainer ring is shown carrying a plurality of spheres, typically steel spheres, on a circular race formed in an upper surface of the ring, which race corresponds to the race 13 formed in the collar portion of the sensor housing 5. The ring 17 carrying the spheres 16 is in this FIG. 7 shown separated from the housing, which corresponds to an interim relative positioning of these members during installation of the sensor unit, and it will be understood that when the high temperature electronic capacitive sensor unit comprising the connecting arrangement of the invention has been installed in the wall, the spheres 16 are in contact with both the race 13 in the collar of the sensor housing 5 and the race formed in the retainer ring 17.

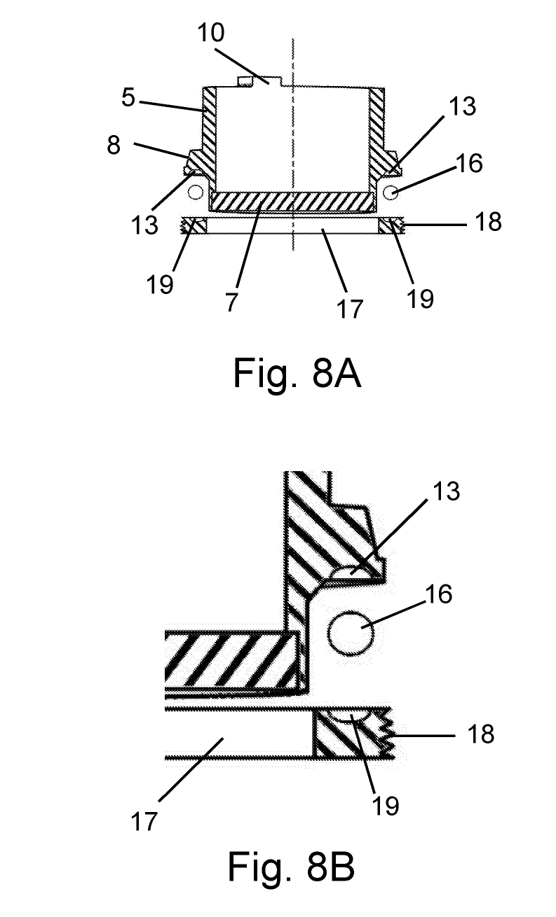

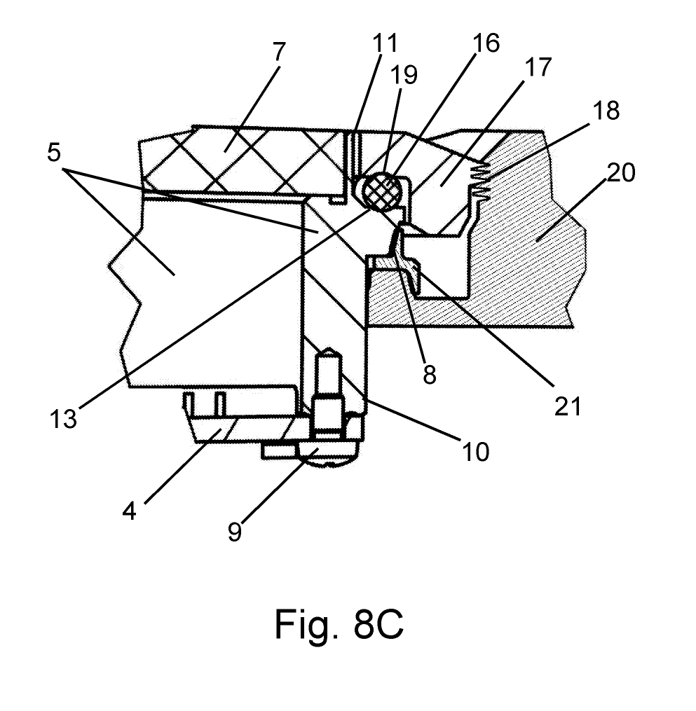

Referring now to FIG. 8A, the details of the arrangement for fastening the high temperature electronic capacitive sensor unit to a wall of a hull, container or probe housing that were illustrated in FIG. 7 are in this FIG. 8A shown in a cross section view. Accordingly, the shape of race 19 arranged in the retainer ring 17 to receive the spheres 16 is made visible, while the spheres are shown “levitated” in a space between the race 9 and the race 13 not to occlude the illustration of these races. It will be understood that the retainer ring 17 has an opening that is dimensioned for allowing the retainer ring 17 to pass over the window holding portion 11 of the sensor housing 5.

Referring now to FIG. 8B, the details of parts of the arrangement for fastening the high temperature electronic capacitive sensor unit to a wall of a hull, container or probe housing that were illustrated in FIG. 8A shown in an enlarged cross section view, for a better understanding of the cross section profiles of the races 13 and 19 as adapted to receive the spheres 16, so as to allow a retention force applied by the retainer ring as its threads are engaged in threads of a wall to which the sensor unit is mounted to become a purely axial force, and no tangential force is coupled from the retainer ring during its rotation when torqued to fasten the sensor in a circular hole in the wall.

Referring now to FIG. 8C, further the details of parts of the arrangement for fastening the high temperature electronic capacitive sensor unit to a wall of a hull, container or probe housing similar to what has been illustrated in FIGS. 8A and 8B are shown in an enlarged cross section view, now with the high temperature electronic capacitive sensor unit completely installed and fixedly mounted in the wall 20 of a hull, container or probe housing, such as e.g. a wall of the tubular probe housing 400 illustrated in FIG. 9. In this embodiment being illustrated in FIG. 8C, an improved sealing arrangement has been implemented, comprising also a metallic sealing member 21 which is arranged between a ring shaped surface of the wall 20, which ring shaped surface has a diameter that corresponds closely to that of the collar portion of the sensor housing 5, and the shape and overall diameter of the beveled or aslant (frustoconical) surface 8 of the collar portion. The threaded outer portion 18 of the retainer ring 17 is well engaged in a correspondingly threaded portion of the wall 20, so as to apply a force on the spheres 16 that is being coupled in a direction that is substantially purely perpendicular to the race or raceway surface 13 of the collar portion of the sensor housing 5 and the race or raceway surface 19 of the retainer ring 17. Thereby, the no special arrangement is required in order to keep the high temperature electronic capacitive sensor unit comprising the connecting arrangement of the invention in a desired position in the wall 20 when a high torque is being applied to the retainer ring 17 for obtaining a reliable high pressure, high temperature sealing at the sealing member 21, and any risk of damage to cables soldered to the PCB 1 due to relative rotation of the sensor unit the high temperature electronic capacitive sensor unit comprising the connecting arrangement of the invention relative to the wall 20 has been eliminated.

### REFERENCE NUMERALS:

1 Secondary printed circuit board—PCB
2 Second metal connecting member of a second gender
3 First metal connecting member of a first gender
4 Primary printed circuit board—PCB
5 Sensor housing
6 Pad for insoldering cable
7 Dielectric window with plate electrode surface
8 Sealing surface on collar
9 Fastener for primary PCB
10 Raised sensor housing portion
11 Window holding portion of sensor housing
12 Cable guiding hole
13 Ball/sphere race/raceway portion of sensor mounting collar
14 Standoff mount for secondary PCB
15 Fastener for secondary PCB
16 Ball/sphere
17 Threaded retaining ring
18 Threaded (outside) portion of threaded retaining ring
19 Ball/sphere race/raceway portion of threaded retaining ring
20 Wall of hull, container or probe housing (400)
21 Sealing member
300 Medium to be characterized or measured

1. A method for connecting a high temperature cable to a circuit board, comprising:
soldering a plurality of connecting elements directly on a circuit board and a soldering a plurality of mating connecting elements to a secondary circuit board including soldering pads for a cable.

2. A high temperature electronic capacitive sensor with a connection arrangement, comprising:
a primary electronics board, which comprises a primary printed circuit board fastened to a sensor housing and populated with a plurality of high temperature electronic components and integrated circuits and for connectivity provided with a plurality of first connecting members which include metal connecting members of a first gender that are connected and attached by high temperature solder to conducting paths or pads on the primary printed circuit board, the first connecting members which include elongated connector pins of relatively small diameter configured to be received in a hollow first connecting member of a second gender in order to create an electrical connection arrangement, the primary printed circuit board fastened by first fasteners to raised portions of one end of the sensor housing, so as to be located close to a dielectric window and an associated measuring capacitor plate electrode carried by the window, thereby minimizing thermal contact between the sensor housing and the primary printed circuit board, while obtaining stable electrical conditions within the sensor assembly and keeping a centrally located wire that connects the plate electrode to the electronics carried by the primary printed circuit board as short and stable as possible,
a connector board comprising the secondary printed circuit board being provided with a plurality of second connecting members, which include metal connecting members of the second gender, being a female, a hollow connector, configured to receive male metal connecting members, pin shaped first connecting members of the first gender, in order to create an electrical connection arrangement, the second connecting members which include elongated metal connecting members comprising an outer diameter that is substantially larger than the outer diameter of the first connecting members, and the secondary printed circuit board including conventional conductive paths configured to connect the second connecting members with conducting pads to which conductors of the cable are solderable, whereby heat transferred from the sensor housing to the conductive pads, via the high temperature primary printed circuit board, the first male connecting members, the second female connecting members and the secondary printed circuit board, is considerably reduced, and conductors of the cable are solderable to the pads by low temperature solder.

3. The sensor of claim 2, wherein the low temperature solder comprises a solder used in commercial grade electronic equipment for operation in temperatures up to about 130° C.

4. The sensor of claim 2, wherein the sensor housing comprises:
a collar portion of the sensor housing of the high temperature electronic capacitive sensor sealingly in an opening in a wall of a high pressure hull, the sensor including a first race for receiving a plurality of solid spheres, a retainer ring including a second race for receiving the plurality of solid spheres and on a circumference threads being configured to engage in corresponding threads provided in the opening, and substantially all of the plurality of the solid spheres located in contact with both of the first and second races.

5. The sensor of claim 2, wherein the first gender is a male gender.

6. The sensor of claim 3, wherein the sensor housing comprises:
a collar portion of the sensor housing of the high temperature electronic capacitive sensor sealingly in an opening in a wall of a high pressure hull, the sensor including a first race for receiving a plurality of solid spheres, a retainer ring including a second race for receiving the plurality of solid spheres and on a circumference threads being configured to engage in corresponding threads provided in the opening, and substantially all of the plurality of the solid spheres located in contact with both of the first and second races.
